(19) United States
(12) Patent Application Publication
(10) Pub. No.: US 2025/0176381 A1
(43) Pub. Date: May 29, 2025

(54) DISPLAY DEVICE AND METHOD OF MANUFACTURING THE SAME

(71) Applicant: Samsung Display Co., Ltd., Yongin-si (KR)

(72) Inventor: DONGHA LEE, Yongin-si (KR)

(73) Assignee: Samsung Display Co., Ltd., Yongin-si (KR)

(21) Appl. No.: 18/771,096

(22) Filed: Jul. 12, 2024

(30) Foreign Application Priority Data
Nov. 24, 2023 (KR) 10-2023-0165418

(51) Int. Cl. H10K 59/131; H10K 50/115; H10K 59/12

(52) U.S. Cl. CPC H10K 59/131; H10K 50/115; H10K 59/1201

(57) ABSTRACT

A display device includes a base substrate, a barrier wall disposed on the base substrate and provided with a first opening, a first arrangement electrode disposed in the first opening, a second arrangement electrode disposed in the first opening and spaced apart from the first arrangement electrode, and a first light emitting layer disposed in the first opening and including a first quantum dot and an organic light emitting material. The first light emitting layer includes a first portion including the first quantum dot and the organic light emitting material and disposed adjacent to the first arrangement electrode and a second portion including the organic light emitting material and disposed adjacent to the second arrangement electrode.

CROSS-REFERENCE TO RELATED APPLICATION(S)

This application claims priority to and the benefits of Korean Patent Application No. 10-2023-0165418 under 35 U.S.C. § 119, filed on Nov. 24, 2023, in the Korean Intellectual Property Office (KIPO), the entire contents of which are incorporated herein by reference.

### BACKGROUND

### 1. Technical Field

The disclosure relates to a display device including a quantum dot and a method of manufacturing the display device.

### 2. Description of Related Art

Various display devices applied to multimedia devices, such as televisions, mobile phones, tablet computers, navigation devices, and game devices, are being developed. The display devices employ a so-called self-emissive display element that displays images by emitting a light emitting material containing an organic compound.

A light emitting element that employs a quantum dot as its light emitting material to improve a color reproducibility of the display device is also being developed, and a method to enhance the resolution of the display device is required.

### SUMMARY

The disclosure provides a display device including a quantum dot.

The disclosure provides a method of manufacturing the display device.

According to an embodiment of the disclosure, a display device may include a base substrate, a barrier wall disposed on the base substrate and provided with a first opening, a first arrangement electrode disposed in the first opening, a second arrangement electrode disposed in the first opening and spaced apart from the first arrangement electrode, and a first light emitting layer disposed in the first opening and including a first quantum dot and an organic light emitting material.

The first light emitting layer may include a first portion including the first quantum dot and the organic light emitting material and disposed adjacent to the first arrangement electrode and a second portion including the organic light emitting material and disposed adjacent to the second arrangement electrode.

The first quantum dot may have a polarity, and the organic light emitting material may not have a polarity.

The first portion may emit a light having a first color, and the second portion may emit a light having a second color different from the first color.

The first arrangement electrode may receive a voltage lower than a voltage applied to the second arrangement electrode in case that the first quantum dot has a positive charge, and the second arrangement electrode may receive a voltage lower than the voltage applied to the first arrangement electrode in case that the first quantum dot has a negative charge.

The display device may further include a first-first lower electrode disposed on the base substrate and at least partially exposed through the first opening of the barrier wall, a first-second lower electrode disposed on the base substrate and at least partially exposed through the first opening of the barrier wall, and a lower electrode insulation portion disposed between the first-first lower electrode and the first-second lower electrode on the base substrate to insulate the first-first lower electrode from the first-second lower electrode.

The display device may further include a first arrangement insulation portion disposed between the first-first lower electrode and the first arrangement electrode and a second arrangement insulation portion disposed between the first-second lower electrode and the second arrangement electrode.

The display device may further include an upper electrode disposed on the first light emitting layer and the barrier wall.

The display device may further include a hole transport region disposed between the first-first lower electrode and the first light emitting layer and between the first-second lower electrode and the first light emitting layer and an electron transport region disposed between the first light emitting layer and the upper electrode.

The first-first lower electrode may have a thickness different from a thickness of the first-second lower electrode, and the first portion of the first light emitting layer may have a thickness different from a thickness of the second portion of the first light emitting layer.

A distance from an upper surface of the first-first lower electrode to a lower surface of the upper electrode may correspond to a resonant thickness of the light having the first color, and a distance from an upper surface of the first-second lower electrode to the lower surface of the upper electrode may correspond to a resonant thickness of the light having the second color.

The first arrangement electrode and the second arrangement electrode may at least partially overlap a side surface of the barrier wall that defines the first opening in a plan view.

The display device may further include a first conductive line that is in contact with the first arrangement electrode and a second conductive line that is in contact with the second arrangement electrode.

A voltage applied to the first arrangement electrode through the first conductive line may be different from a voltage applied to the second arrangement electrode through the second conductive line.

The display device may further include a second light emitting layer. The barrier wall may be provided with a second opening, the second light emitting layer may be disposed in the second opening and include a second quantum dot, and the second light emitting layer may emit a light having a third color different from the first and second colors.

The first opening may have a size greater than a size of the second opening in a plan view.

The display device may further include a light control layer disposed on the base substrate. The light control layer may include a light blocking portion, a first filter that transmits a light having a first color, a second filter that transmits a light having a second color, and a third filter that transmits a light having a third color.

The first quantum dot may include a core, at least one shell surrounding the core, and a ligand placed outside the shell, and the shell or the ligand may have a polarity.

The first quantum dot may have a first energy level, and the organic light emitting material may have a second energy level higher than the first energy level.

According to an embodiment of the disclosure, a method of manufacturing a display device may include forming a base substrate, a first-first lower electrode on the base substrate, a first-second lower electrode on the base substrate and spaced apart from the first-first lower electrode, and a lower electrode insulation portion between the first-first lower electrode and the first-second lower electrode, forming a barrier wall through which an opening is formed to expose at least a portion of each of the first-first lower electrode and the first-second lower electrode, forming a first arrangement electrode and a second arrangement electrode spaced apart from the first arrangement electrode in the opening, providing a liquid luminescent composition including a quantum dot and an organic light emitting material to the opening, and forming an electric field between the first arrangement electrode and the second arrangement electrode to move the quantum dot in a direction closer to the first arrangement electrode.

The method may further include drying the liquid luminescent composition. The drying of the liquid luminescent composition and the forming of the electric field may be performed through a same process.

According to the above, two different lights are emitted from one light emitting layer included in the display device. Accordingly, the resolution of the display device is improved.

### BRIEF DESCRIPTION OF THE DRAWINGS

The above and other advantages of the disclosure will become readily apparent by reference to the following detailed description when considered in conjunction with the accompanying drawings wherein:

FIG. 1 is a perspective view of a display device according to an embodiment of the disclosure;

FIG. 2 is an exploded perspective view of a display device shown in FIG. 1;

FIG. 3 is a schematic cross-sectional view of a display panel taken along line I-I′ of FIG. 2;

FIG. 4 is a plan view of a display panel according to an embodiment of the disclosure;

FIG. 5 is an enlarged plan view of area AA′ of FIG. 4;

FIG. 6 is a schematic cross-sectional view taken along line II-II′ of FIG. 5;

FIG. 7 is an enlarged schematic cross-sectional view of area BB′ of FIG. 6;

FIG. 8 is a schematic cross-sectional view of a portion of a display device according to an embodiment of the disclosure;

FIG. 9 is a schematic diagram showing a structure of a quantum dot according to an embodiment of the disclosure;

FIG. 10 is a flowchart illustrating a method of manufacturing a display device according to an embodiment of the disclosure; and

FIGS. 11A to 11F are schematic cross-sectional views illustrating processes of a method of manufacturing a display device according to an embodiment of the disclosure.

### DETAILED DESCRIPTION OF THE EMBODIMENTS

The disclosure may be variously modified and realized in many different forms, and thus embodiments will be illustrated in the drawings and described in detail hereinbelow. However, the disclosure should not be limited to the specific disclosed forms, and be construed to include all modifications, equivalents, or replacements included in the spirit and scope of the disclosure.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Like numerals refer to like elements throughout. In the drawings, the thickness, ratio, and dimension of components are exaggerated for effective description of the technical content. In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that, although the terms first, second, etc. may be used herein to describe various elements, these elements should not be limited by these terms. These terms are only used to distinguish one element from another element. Thus, a first element discussed below could be termed a second element without departing from the teachings of the disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure will be described with reference to accompanying drawings.

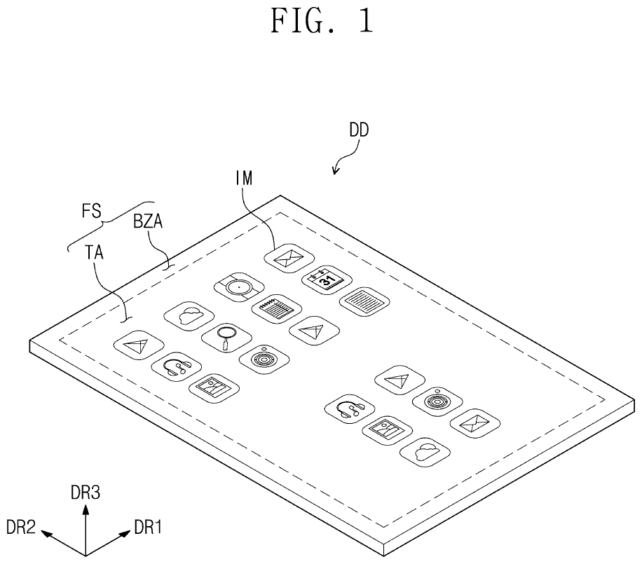

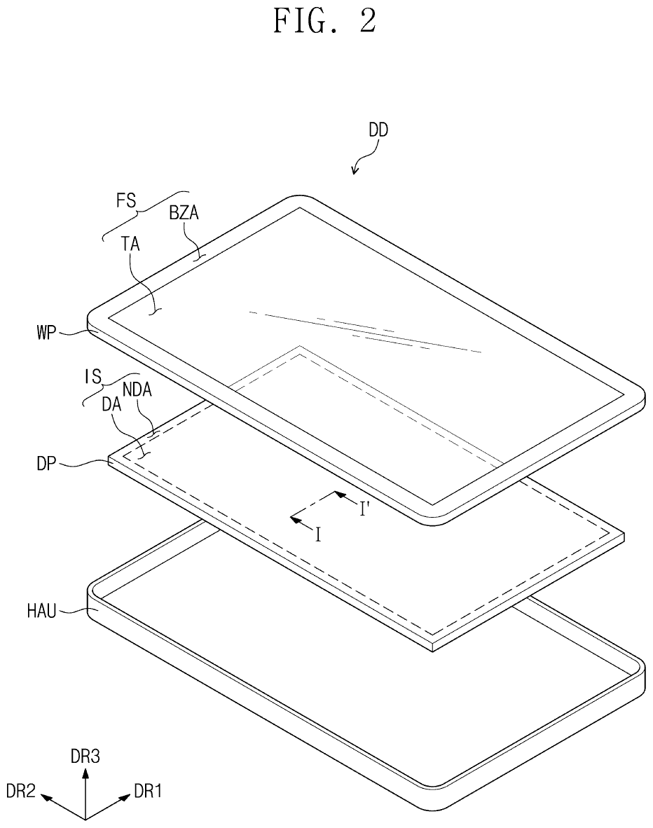

FIG. 1 is a perspective view of a display device DD according to an embodiment of the disclosure. FIG. 2 is an exploded perspective view of the display device DD shown in FIG. 1.

The display device DD may be activated in response to electrical signals and may display images. The display device DD may be applied with various embodiments to provide various users with the images. For example, the display device DD may be applied to a large-sized electronic item, such as a television set or an outdoor billboard. For example, the display device DD may be applied to a small and medium-sized electronic item, such as a monitor, a mobile phone, a tablet computer, a navigation unit, a game unit, etc. However, the disclosure is not limited thereto, and the display device DD may be applied to other electronic items as long as they do not depart from the disclosure.

Referring to FIG. 1, the display device DD may have a rectangular shape with short sides extending in a first direction DR1 and long sides extending in a second direction DR2 in a plan view, however, the shape of the display device DD should not be limited thereto or thereby. The display device DD may have a variety of shapes such as a circular shape, a polygonal shape, etc.

The display device DD may display an image IM through a display surface FS, which is substantially parallel to a plane defined by the first direction DR1 and the second direction DR2, toward a third direction DR3. The third direction DR3 may be substantially parallel to a normal line direction of the display surface FS. The display surface FS in which the image IM is displayed may correspond to a front surface of the display device DD. The image IM may include a video and a still image. FIG. 1 shows application icons as an example of the image IM.

In the disclosure, front (or upper) and rear (or lower) surfaces of each member or each unit of the display device DD may be defined with respect to a direction in which the image IM is displayed. The front and rear surfaces may be opposite to each other in the third direction DR3, and a normal line direction of each of the front and rear surfaces may be substantially parallel to the third direction DR3. A separation distance between the front and rear surfaces may correspond to a thickness in the third direction DR3 of the member (or the unit). In the following descriptions, the expression “when viewed in a plane” or “in a plan view” means a state of being viewed in the third direction DR3. In the following descriptions, the expression “when viewed in a cross-section” or “in a cross-sectional view” means a state of being viewed in the first direction DR1 or the second direction DR2. Directions indicated by the first, second, and third directions DR1, DR2, and DR3 may be relative to each other and may be changed to other directions.

The display surface FS of the display device DD through which the image IM is displayed may correspond to the front surface of the display device DD and a front surface FS of a window WP (refer to FIG. 2). Accordingly, the display surface and the front surface of the display device DD and the front surface of the window WP will be assigned with the same reference numeral. Although not shown in drawings, the display device DD may include a foldable display device including a folding area and a non-folding area or a bendable display device including at least one bending portion.

Referring to FIG. 2, the display device DD may include the window WP, a display panel DP, and a housing HAU.

The window WP may include an optically transparent insulating material. The window WP may include a transmissive area TA and a bezel area BZA. A user may view the image IM provided through the transmissive area TA corresponding to the front surface FS of the window WP.

FIGS. 1 and 2 illustrate that the transmissive area TA has a quadrangular shape with rounded vertices, however, the disclosure is not limited thereto. The transmissive area TA may have a variety of shapes and should not be particularly limited.

The transmissive area TA may be an optically transparent area. The bezel area BZA may be an area having a relatively lower transmittance than the transmissive area TA. The bezel area BZA may have a color. The bezel area BZA may be disposed adjacent to the transmissive area TA and may surround the transmissive area TA in a plan view. The bezel area BZA may define a shape of the transmissive area TA. However, the disclosure should not be limited thereto or thereby, and the bezel area BZA may be disposed adjacent to only one side of the transmissive area TA or may be omitted.

The display panel DP may be disposed under the window WP. The display panel DP may have a configuration that substantially generates an image IM. The display panel DP may display the image IM through a display surface IS, and a user may view the image IM through the transmissive area TA. The display panel DP may include a display area DA and a non-display area NDA. The display area DA may be activated in response to electrical signals. The non-display area NDA may be covered by the bezel area BZA. The non-display area NDA may be defined adjacent to the display area DA. The non-display area NDA may surround the display area DA in a plan view.

The housing HAU may accommodate the display panel DP. The housing HAU may cover the display panel DP, and an upper surface of the display panel DP, i.e., the display surface IS, may be exposed. The housing HAU may cover a side surface and a bottom surface of the display panel DP, and the upper surface may be entirely exposed, however, the disclosure should not be limited thereto or thereby. According to an embodiment, the housing HAU may cover a portion of the upper surface in addition to the side surface and the bottom surface of the display panel DP.

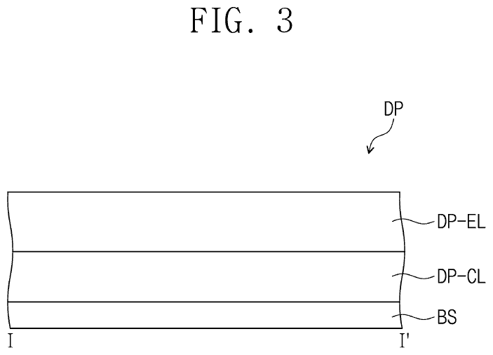

FIG. 3 is a schematic cross-sectional view of the display panel DP taken along line I-I′ of FIG. 2.

In an embodiment, the display panel DP may be a light emitting type display panel. For example, the display panel DP may be a quantum dot light emitting display panel including a quantum dot light emitting element, however, the disclosure should not be limited thereto or thereby. According to an embodiment, the display panel DP may be an organic light emitting display panel including an organic electroluminescence element.

The display panel DP may include a base substrate BS, a circuit element layer DP-CL disposed on the base substrate BS, and a display element layer DP-EL disposed on the circuit element layer DP-CL.

The base substrate BS may be disposed at a lowermost position of the display panel DP and may provide a base surface on which components of the display panel DP are disposed.

The circuit element layer DP-CL may be disposed on the base substrate BS. The circuit element layer DP-CL may include multiple insulating layers and a circuit element.

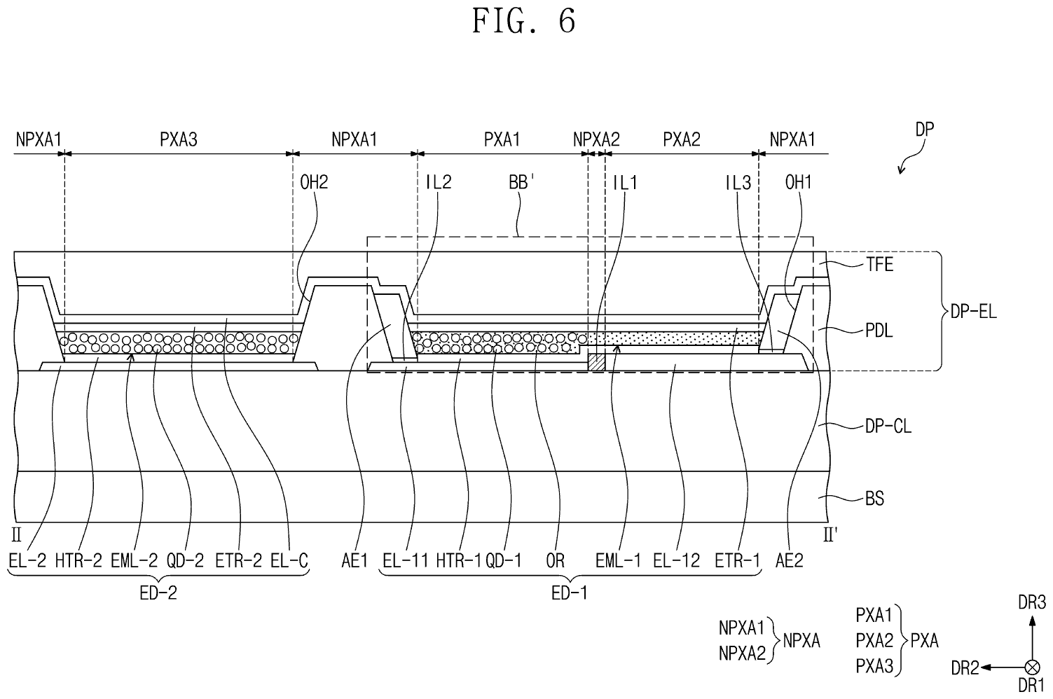

The display clement layer DP-EL may be disposed on the circuit element layer DP-CL. The display element layer DP-EL may include a pixel definition layer PDL (refer to FIG. 6), a display element ED-2 (refer to FIG. 6), and an encapsulation layer TFE (refer to FIG. 6).

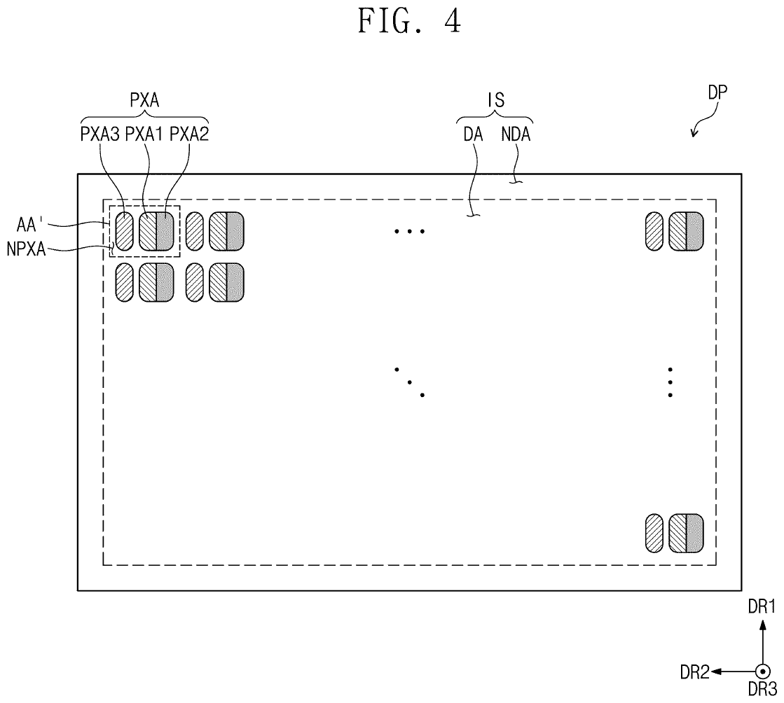

FIG. 4 is a plan view of the display panel DP according to an embodiment of the disclosure.

The display surface IS of the display panel DP may include the display area DA and the non-display area NDA. The display area DA of the display panel DP may include a light emitting area PXA and a peripheral area NPXA.

The light emitting area PXA may be defined as an area from which a light exits in the display area DA. The light emitting areas PXA may be arranged with a specific rule over the display area DA. For example, the light emitting areas PXA may be arranged in the first direction DR1 and the second direction DR2.

The light emitting areas PXA arranged in a same row may be defined as a pixel row. In an embodiment, the pixel row may be provided in plural. The pixel rows may be arranged spaced apart from each other in the first direction DR1. A pixel row may include the light emitting areas PXA arranged spaced apart from each other in the second direction DR2.

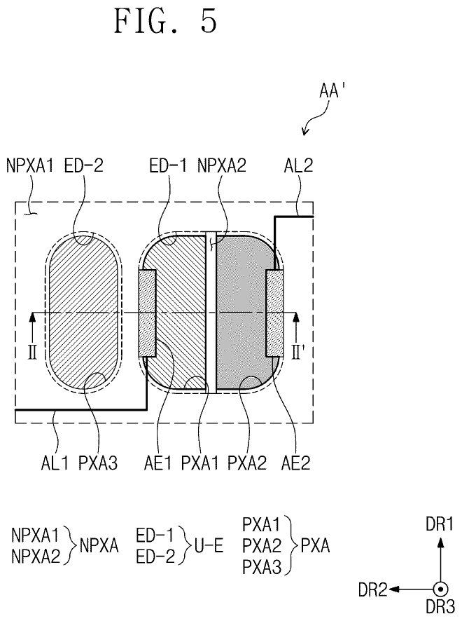

A light emitting area PXA may include first, second, and third light emitting areas PXA1, PXA2, and PXA3. In a light emitting area PXA, the first, second, and third light emitting areas PXA1, PXA2, and PXA3 may be arranged in the second direction DR2 in the order of the third light emitting area PXA3, the first light emitting area PXA1, and the second light emitting area PXA2. Accordingly, the third light emitting area PXA3 and the second light emitting area PXA2 may be spaced apart from each other with the first light emitting area PXA1 interposed between the third light emitting area PXA3 and the second light emitting area PXA2 in a light emitting area PXA. The first light emitting area PXA1 and the second light emitting area PXA2 may be disposed adjacent to each other and may overlap a light emitting element ED-1 (refer to FIG. 5) in a plan view, and this will be described below with reference to FIG. 5.

Each of the first to third light emitting areas PXA1 to PXA3 may be arranged in the first direction DR1. In the disclosure, the expression “The light emitting areas are arranged in one direction” may mean that the light emitting areas of the same type are arranged consecutively in one direction.

The first to third light emitting areas PXA1 to PXA3 shown in FIG. 4 may be arranged in a stripe pattern, however, the arrangement of the first to third light emitting areas PXA1 to PXA3 should not be limited thereto or thereby. For example, the arrangement of the first to third light emitting areas PXA1 to PXA3 may be provided in various combinations depending on characteristics of a display quality required for the display panel DP. For example, the first to third light emitting areas PXA1 to PXA3 may be arranged in a PENTILET pattern or a Diamond Pixel™ pattern.

The peripheral area NPXA may correspond to a remaining area of the display area DA, excluding the light emitting area PXA. The peripheral area NPXA may be disposed adjacent to the light emitting area PXA.

FIG. 5 is an enlarged plan view of area AA′ of FIG. 4.

Referring to FIG. 5, the display panel DP (refer to FIG. 4) may include a unit element U-E, first and second arrangement electrodes AE1 and AE2, and first and second conductive lines ALI and AL2. The unit element U-E may include first and second light emitting elements ED-1 and ED-2.

For the convenience of explanation, FIG. 5 schematically shows first lower electrodes EL-11 and EL-12 (refer to FIG. 6) included in the first light emitting element ED-1 and a second lower electrode EL-2 (refer to FIG. 6) included in the second light emitting element ED-2 with a dotted line. The lower electrodes EL-2, EL-11, and EL-12 indicated by a dotted line may correspond to light emitting elements.

In a plan view, the first light emitting element ED-1 and the second light emitting element ED-2 may be spaced apart from each other. The first light emitting element ED-1 may have a size greater than a size of the second light emitting element ED-2 in a plan view.

The first and second arrangement electrodes AE1 and AE2 may overlap the first light emitting element ED-1 in a plan view. The first arrangement electrode AE1 and the second arrangement electrode AE2 may be disposed to face each other. As shown in FIG. 5, the first and second arrangement electrodes AE1 and AE2 may have substantially the same rectangular shape in a plan view. However, the shape of the first and second arrangement electrodes AE1 and AE2 should not be limited to the rectangular shape as long as the first and second arrangement electrodes AE1 and AE2 face each other and are spaced apart from each other in a plan view, and the first and second arrangement electrodes AE1 and AE2 may have different shapes from each other.

An end of the first conductive line AL1 may be in contact with the first arrangement electrode AE1, and another end of the first conductive line AL1 may be connected to a power supply source (not shown) of the circuit element layer DP-CL. An end of the second conductive line AL2 may be in contact with the second arrangement electrode AE2, and another end of the second conductive line AL2 may be connected to a power supply source (not shown) of the circuit element layer DP-CL.

The first arrangement electrode AE1 and the second arrangement electrode AE2 may receive voltages through the first conductive line AL1 and the second conductive line AL2, respectively. The voltage applied to the first arrangement electrode AE1 through the first conductive line AL1 may be defined as a first voltage, and the voltage applied to the second arrangement electrode AE2 through the second conductive line AL2 may be defined as a second voltage. The first voltage may be different from the second voltage.

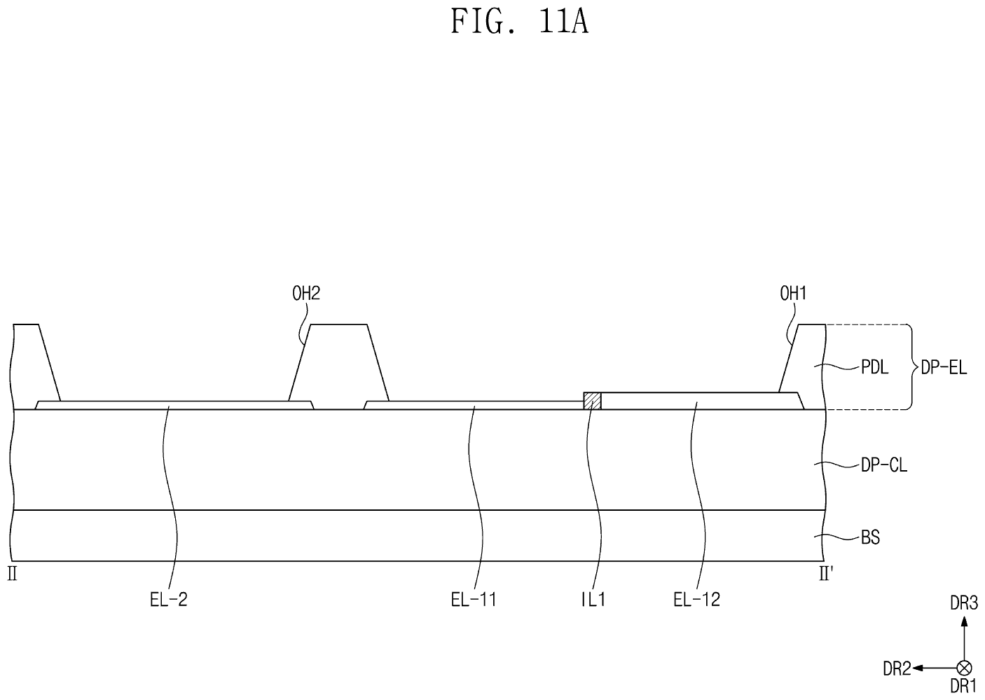

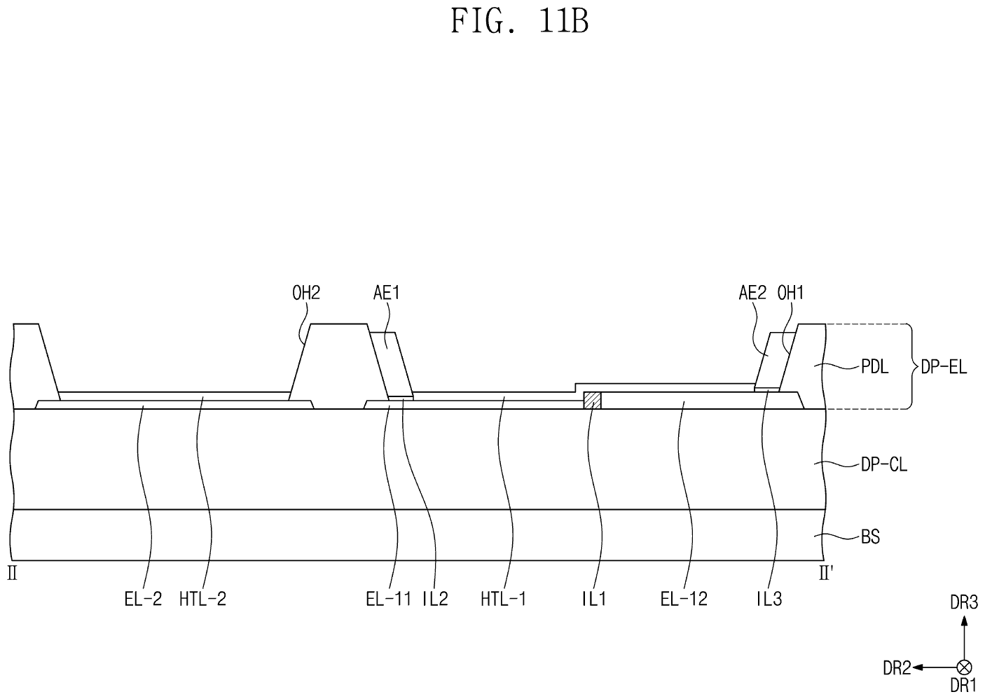

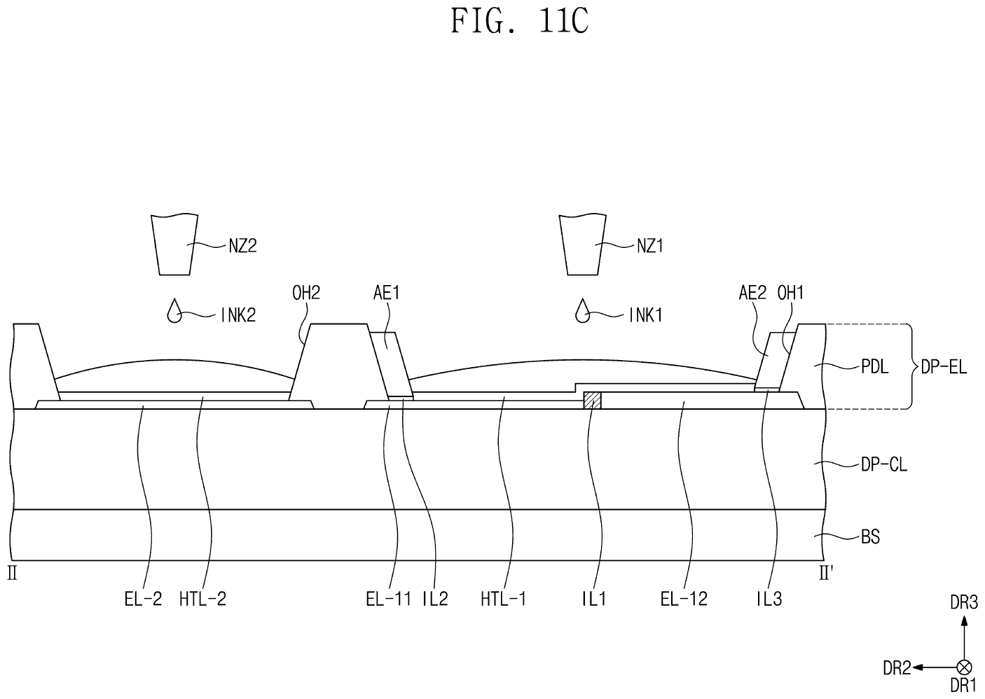

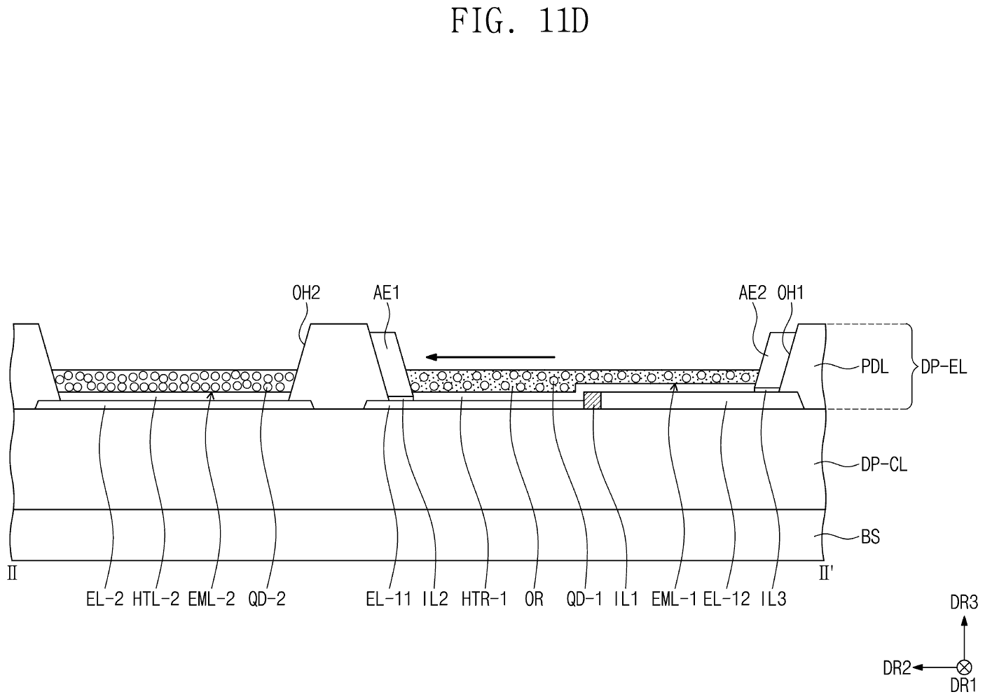

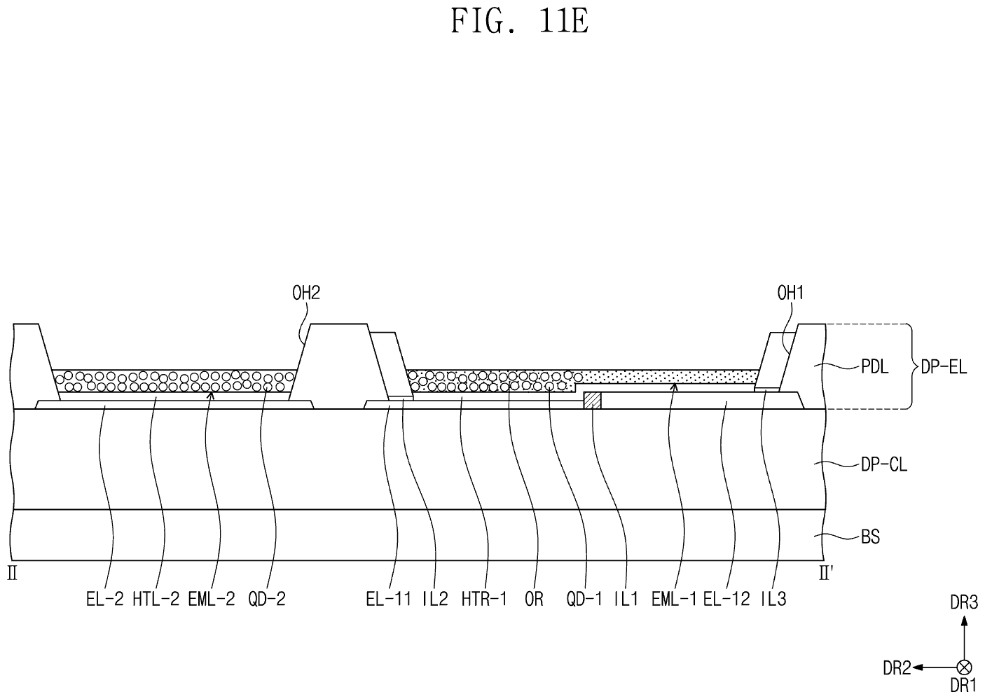

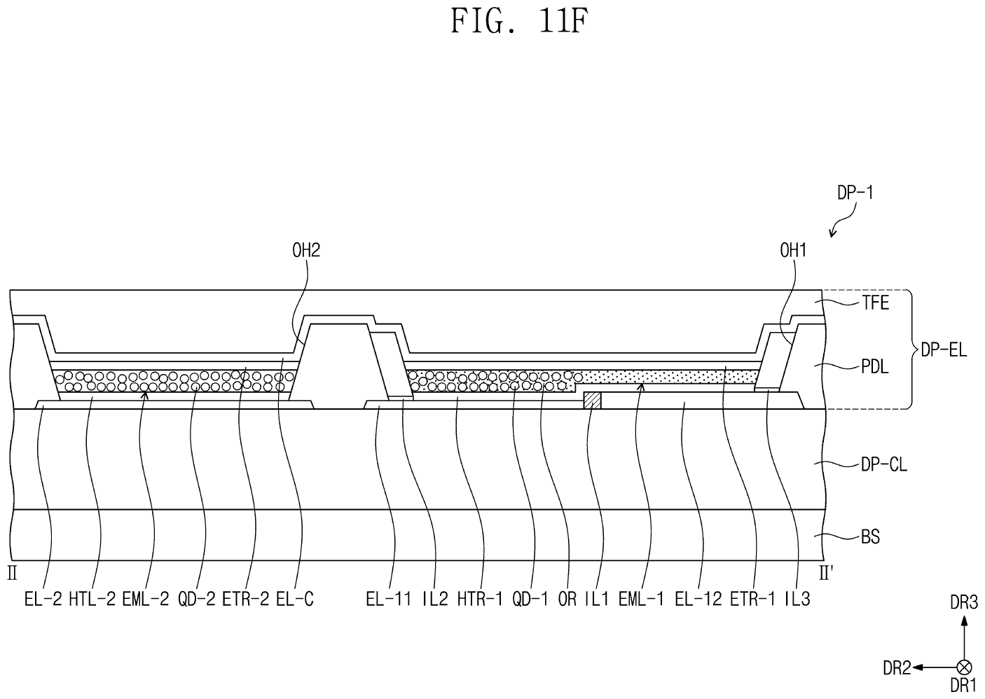

Accordingly, an electric field may be formed between the first arrangement electrode AE1 and the second arrangement electrode AE2 to which the voltages are applied. A polar material provided between the first arrangement electrode AE1 and the second arrangement electrode AE2 may move by electric force caused by the electric field formed between the first arrangement electrode AE1 and the second arrangement electrode AE2. A process of forming a first light emitting layer EML-1 (refer to FIG. 6) according to movement of a first quantum dot QD-1 with polarity will be described below with reference to FIGS. 6 and 11D.

The first and second light emitting areas PXA1 and PXA2 may overlap the first light emitting element ED-1 in a plan view. The first and second light emitting areas PXA1 and PXA2 may be areas from which lights generated by the first light emitting element ED-1 are emitted. However, the first light emitting area PXA1 may emit the light having a first color, and the second light emitting area PXA2 may emit the light having a second color different from the first color. For example, the display panel DP (refer to FIG. 4) may emit two different lights from each other using one light emitting element ED-1.

The third light emitting area PXA3 may overlap the second light emitting element ED-2 in a plan view. The third light emitting area PXA3 may be an area from which a light generated by the second light emitting element ED-2 and having a third color different from the first and second colors is emitted.

In an embodiment, the first color may be a green color, the second color may be a blue color, and the third color may be a red color. In another embodiment, the second color may be the green color, and the third color may be the blue color. However, the disclosure should not be limited thereto or thereby. According to an embodiment, the first color may be the red color, the second color may be the blue color, and the third color may be the green color.

The peripheral area NPXA may include a first peripheral area NPXA1 and a second peripheral area NPXA2. The first peripheral area NPXA1 may correspond to the pixel definition layer PDL (refer to FIG. 6) or the first and second arrangement electrodes AE1 and AE2. The second peripheral area NPXA2 may correspond to a first arrangement insulation portion IL1 (refer to FIG. 6).

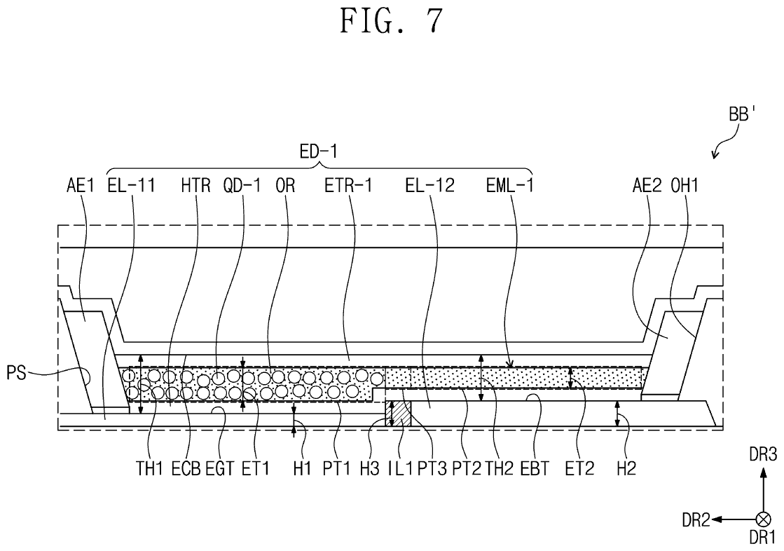

FIG. 6 is a schematic cross-sectional view taken along line II-II′ of FIG. 5. FIG. 7 is an enlarged schematic cross-sectional view of area BB′ of FIG. 6.

Referring to FIG. 6, the display panel DP may include the base substrate BS, the circuit element layer DP-CL, and the display element layer DP-EL.

The base substrate BS may provide a base surface on which components included in the display panel DP are stacked. The base substrate BS may include a synthetic resin layer.

The synthetic resin layer may include a thermosetting resin. For example, the synthetic resin layer may be a polyimide-based resin layer, however, the disclosure should not be limited thereto or thereby. The synthetic resin layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. The base substrate BS may be a glass substrate, a metal substrate, or an organic/inorganic composite material substrate. The base substrate BS may be a flexible substrate that is readily bent or folded.

The circuit element layer DP-CL may be disposed on the base substrate BS. The circuit element layer DP-CL may include multiple insulating layers and a circuit element. The insulating layers may include at least one inorganic layer and at least one organic layer. The circuit element may include signal lines, driving circuits, and the like. The driving circuit may include a pixel driving circuit and a sensing driving circuit.

The display element layer DP-EL may be disposed on the circuit element layer DP-CL. The display element layer DP-EL may include the pixel definition layer PDL, the light emitting elements ED-1 and ED-2, the first and second arrangement electrodes AE1 and AE2, the first arrangement insulation portion IL1, second and third arrangement insulation portions IL2, and IL3, and the encapsulation layer TFE.

In the specification, the first arrangement insulation portion IL1 may be expressed as “lower electrode insulation portion”.

The first light emitting element ED-1 may include the first lower electrodes EL-11 and EL-12, a first hole transport region HTR-1, the first light emitting layer EML-1, a first electron transport region ETR-1, and an upper electrode EL-C.

The second light emitting element ED-2 may include the second lower electrode EL-2, a second hole transport region HTR-2, a second light emitting layer EML-2, a second electron transport region ETR-2, and the upper electrode EL-C.

The first lower electrodes EL-11 and EL-12 may be disposed on the circuit element layer DP-CL. The first lower electrodes EL-11 and EL-12 may include a first-first lower electrode EL-11 and a first-second lower electrode EL-12. The first-first lower electrode EL-11 may be spaced apart from the first-second lower electrode EL-12.

The second lower electrode EL-2 may be disposed on the circuit element layer DP-CL. The second lower electrode EL-2 may have a continuous single body different from the first lower electrodes EL-11 and EL-12.

The first and second lower electrodes EL-11, EL-12, and EL-2 may be formed of a metal alloy or a conductive compound. The first and second lower electrodes EL-11, EL-12, and EL-2 may be referred to as a pixel electrode. The first and second lower electrodes EL-11, EL-12, and EL-2 may be an anode.

The first and second lower electrodes EL-11, EL-12, and EL-2 may be a reflective electrode, however, the disclosure should not be limited thereto or thereby. For example, the first and second lower electrodes EL-11, EL-12, and EL-2 may be a transmissive electrode or a semi-transmissive electrode. In an embodiment that the first and second lower electrodes EL-11, EL-12, and EL-2 are the semi-transmissive electrode or the reflective electrode, each of the first and second lower electrodes EL-11, EL-12, and EL-2 may include Ag, Mg, Cu, Al, Pt, Pd, Au, Ni, Nd, Ir, Cr, Li, Ca, LiF/Ca, LiF/Al, Mo, Ti, W, a compound thereof, or a mixture thereof, e.g., a mixture of Ag and Mg.

According to an embodiment, the first and second lower electrodes EL-11, EL-12, and EL-2 may have a multi-layer structure of a reflective layer or a semi-transmissive layer, which is formed of the above-mentioned material, and a transparent conductive layer formed of indium tin oxide (ITO), indium zinc oxide (IZO), zinc oxide (ZnO), or indium tin zinc oxide (ITZO). For example, each of the lower electrodes may have a three-layer structure of ITO/Ag/ITO.

The first arrangement insulation portion IL1 may be disposed between the first-first lower electrode EL-11 and the first-second lower electrode EL-12 on the circuit element layer DP-CL. The first arrangement insulation portion IL1 may allow the first-first lower electrode EL-11 to be spaced apart from and electrically insulated from the first-second lower electrode EL-12. In FIG. 6, the first arrangement insulation portion IL1 has a quadrangular shape in a cross-sectional view. However, the cross-sectional shape of the first arrangement insulation portion IL1 should not be limited thereto or thereby as long as the first-first lower electrode EL-11 and the first-second lower electrode EL-12 are electrically insulated from each other. The first arrangement insulation portion IL1 may include an insulating material.

The pixel definition layer PDL may be disposed on the circuit element layer DP-CL. The pixel definition layer PDL may cover at least a portion of the first lower electrodes EL-11 and EL-12 and at least a portion of the second lower electrode EL-2.

The pixel definition layer PDL may include a silicon-based inorganic material. For example, the pixel definition layer PDL may include at least one of silicon nitride, silicon oxynitride, and silicon oxide. In an embodiment, the pixel definition layer PDL may be referred to as a barrier wall.

The pixel definition layer PDL may be provided with a first opening OH1 and a second opening OH2. At least a portion of the first-first lower electrode EL-11 and at least a portion of the first-second lower electrode EL-12 may be exposed through the first opening OH1, and at least a portion of the second lower electrode EL-2 may be exposed through the second opening OH2.

In an embodiment, the portion of the first-first lower electrode EL-11 exposed through the first opening OH1 may correspond to the first light emitting area PXA1, the portion of the first-second lower electrode EL-12 exposed through the first opening OH1 may correspond to the second light emitting area PXA2, and the portion of the second lower electrode EL-2 exposed through the second opening OH2 may correspond to the third light emitting area PXA3.

In a plan view, the first opening OH1 may have a size greater than a size of the second opening OH2. For example, a sum of a size of the first light emitting area PXA1 and a size of the second light emitting area PXA2 may be greater than a size of the third light emitting area PXA3 in a plan view.

The first hole transport region HTR-1 may be disposed on the first lower electrodes EL-11 and EL-12. Although not shown in figures, the first hole transport region HTR-1 may include a hole injection layer, a hole transport layer, and/or an electron block layer as its sub-functional layer.

The second hole transport region HTR-2 may be disposed on the second lower electrode EL-2. Although not shown in figures, the second hole transport region HTR-2 may include a hole injection layer, a hole transport layer, and/or an electron block layer as its sub-functional layer.

The first light emitting layer EML-1 may be disposed in the first opening OH1. The first light emitting layer EML-1 may be disposed on the first lower electrodes EL-11 and EL-12.

The first light emitting layer EML-1 may include the first quantum dot QD-1 and an organic light emitting material OR. The first light emitting layer EML-1 may be formed from a liquid luminescent composition including the first quantum dot QD-1, the organic light emitting material OR, and an organic solvent.

According to an embodiment, one first light emitting element ED-1 may include two first lower electrodes EL-11 and EL-12, and thus, two different types of charges may be provided in one first light emitting layer EML-1. For example, the first-first lower electrode EL-11 may provide charges to a portion of the first light emitting layer EML-1 overlapping the first light emitting area PXA1 in a plan view, and the first-second lower electrode EL-12 may provide charges to a portion of the first light emitting layer EML-1 overlapping the second light emitting area PXA2 in a plan view. Accordingly, the first light emitting layer EML-1 included in the display panel DP may emit two different types of lights.

The second light emitting layer EML-2 may be disposed in the second opening OH2. The second light emitting layer EML-2 may be disposed on the second lower electrode EL-2. The second light emitting layer EML-2 may include a second quantum dot QD-2. The second light emitting layer EML-2 may be formed of a liquid luminescent composition including the second quantum dot QD-2 and an organic solvent. The second light emitting layer EML-2 may emit the light having the third color different from the first color and the second color.

The second arrangement insulation portion IL2 may be disposed between the first arrangement electrode AE1 and the first-first lower electrode EL-11. The second arrangement insulation portion IL2 may prevent the first arrangement electrode AE1 from being electrically connected to the first-first lower electrode EL-11. The first-first lower electrode EL-11 and the first arrangement electrode AE1 may be spaced apart from each other with the second arrangement insulation portion IL2 interposed between the first-first lower electrode EL-11 and the first arrangement electrode AE1. The second arrangement insulation portion IL2 may include an insulating material.

The third arrangement insulation portion IL3 may be disposed between the second arrangement electrode AE2 and the first-second lower electrode EL-12. The third arrangement insulation portion IL3 may prevent the second arrangement electrode AE2 from being electrically connected to the first-second lower electrode EL-12. The first-second lower electrode EL-12 and the second arrangement electrode AE2 may be spaced apart from each other with the third arrangement insulation portion IL3 interposed between the first-second lower electrode EL-12 and the second arrangement electrode AE2. The third arrangement insulation portion IL3 may include an insulating material.

The first arrangement electrode AE1 may be disposed on the first-first lower electrode EL-11, and the second arrangement electrode AE2 may be disposed on the first-second lower electrode EL-12. The first arrangement electrode AE1 and the second arrangement electrode AE2 may be disposed to face each other. The first arrangement electrode AE1 and the second arrangement electrode AE2 may be spaced apart from each other.

As shown in FIG. 6, the first arrangement electrode AE1 and the second arrangement electrode AE2 may have a parallelogram shape in a cross-sectional view and may have asymmetrical shapes. However, the disclosure should not be limited thereto or thereby, and in a cross-sectional view, the first arrangement electrode AE1 and the second arrangement electrode AE2 may have symmetrical shapes or a shape other than the parallelogram shape.

The first arrangement electrode AE1 and the second arrangement electrode AE2 may be in contact with a side surface PS (refer to FIG. 7) of the pixel definition layer PDL, which defines the first opening OH1, however, the disclosure should not be limited thereto or thereby. According to an embodiment, the first arrangement electrode AE1 and the second arrangement electrode AE2 may be spaced apart from the side surface PS of the pixel definition layer PDL.

The voltages may be applied to the first arrangement electrode AE1 and the second arrangement electrode AE2 through the first conductive line AL1 (refer to FIG. 5) and the second conductive line AL2 (refer to FIG. 5), respectively. In case that different voltages are applied to the first arrangement electrode AE1 and the second arrangement electrode AE2, the electric field may be formed between the first arrangement electrode AE1 and the second arrangement electrode AE2. Accordingly, the quantum dots disposed between the first arrangement electrode AE1 and the second arrangement electrode AE2 may move in a direction. FIG. 6 schematically shows a state after the first quantum dot QD-1 included in the first light emitting layer EML-1 moved in the second direction DR2 according to an embodiment.

The first electron transport region ETR-1 may be disposed on the first light emitting layer EML-1. The first electron transport region ETR-1 may be disposed between the first light emitting layer EML-1 and the upper electrode EL-C. Although not shown in figures, the first electron transport region ETR-1 may include an electron injection layer, an electron transport layer, and a hole block layer as its sub-functional layer.

The second electron transport region ETR-2 may be disposed on the second light emitting layer EML-2. The second electron transport region ETR-2 may be disposed between the second light emitting layer EML-2 and the upper electrode EL-C. Although not shown in figures, the second electron transport region ETR-2 may include an electron injection layer, an electron transport layer, and a hole layer as its sub-functional layer.

Each of the first hole transport region HTR-1 and the first electron transport region ETR-1 may be patterned by a printing process and may be provided in the first opening OH1 defined by the pixel definition layer PDL. Each of the second hole transport region HTR-2 and the second electron transport region ETR-2 may be patterned by a printing process and may be provided in the second opening OH2 defined by the pixel definition layer PDL by a printing process.

The upper electrode EL-C may be entirely disposed to cover the first and second electron transport regions ETR-1 and ETR-2, the first and second arrangement electrodes AE1 and AE2, and the pixel definition layer PDL. The upper electrode EL-C may be a common electrode. The upper electrode EL-C may be the cathode or the anode. For example, in case that the lower electrodes EL-11, EL-12, and EL-2 are the anode, the upper electrode EL-C may be the cathode, and in case that the lower electrodes EL-11, EL-12, and EL-2 are the cathode, the upper electrode EL-C may be the anode.

The upper electrode EL-C may be a transmissive electrode, a semi-transmissive electrode, or a reflective electrode.

In an embodiment that the upper electrode EL-C is a transmissive electrode, the upper electrode EL-C may include a transparent metal oxide, e.g., indium tin oxide (ITO), indium zinc oxide (IZO), zinc oxide (ZnO), indium tin zinc oxide (ITZO), etc.

In an embodiment that the upper electrode EL-C is a semi-transmissive electrode or the reflective electrode, the upper electrode EL-C may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof, e.g., AgMg, AgYb, or MgAg. According to an embodiment, the upper electrode EL-C may have a multi-layer structure of a reflective layer or a semi-transmissive layer, which is formed of the above-mentioned material, and a transparent conductive layer formed of indium tin oxide (ITO), indium zinc oxide (IZO), zinc oxide (ZnO), or indium tin zinc oxide (ITZO). For example, the upper electrode EL-C may include the above-mentioned metal materials, a combination of two or more metal materials selected from the above-mentioned metal materials, or an oxide of the above-mentioned metal materials.

Although not shown in figures, a capping layer may be disposed on the upper electrode EL-C.

The encapsulation layer TFE may be disposed on the circuit element layer DP-CL and cover the display element layer DP-EL. The encapsulation layer TFE may include an organic layer or an inorganic layer. The encapsulation layer TFE may prevent reliability of the display device DD (refer to FIG. 1) from being deteriorated, which is caused by moisture, oxygen, or a foreign substance that permeates the display device DD.

Referring to FIG. 7, the first light emitting layer EML-1 may include first, second, and third portions PT1, PT2, and PT3.

The first portion PT1 may include the first quantum dot QD-1 and the organic light emitting material OR and may be adjacent to the first arrangement electrode AE1. The second portion PT2 may include the organic light emitting material OR and may be adjacent to the second arrangement electrode AE2. The third portion PT3 may be disposed between the first portion PT1 and the second portion PT2 and may overlap the first arrangement insulation portion IL1 in a plan view. However, the first, second, and third portions PT1, PT2, and PT3 are distinguished from each other for the convenience of explanation, and the first light emitting layer EML-1 may have a continuous single body.

The first portion PT1 may emit the light having the first color, and the second portion PT2 may emit the light having the second color different from the first color. For example, one first light emitting layer EML-1 may emit two different lights. In an embodiment, the first color may be the green color, and the second color may be the blue color, however, the disclosure should not be limited thereto or thereby. In another embodiment, the first color may be the red color, and the second color may be the blue color.

In an embodiment, the first quantum dot QD-1 may have a polarity, and the organic light emitting material OR may not have a polarity.

In case that the first quantum dot QD-1 has the polarity, the first quantum dot QD-1 may move by forming the electric field in the first light emitting layer EML-1. For example, the voltages may be applied to the first arrangement electrode AE1 and the second arrangement electrode AE2 to move the first quantum dot QD-1 closer to the first arrangement electrode AE1. For example, in case that the first quantum dot QD-1 has a positive charge, the voltage applied to the first arrangement electrode AE1 may be lower than the voltage applied to the second arrangement electrode AE2, and in case that the first quantum dot QD-1 has a negative charge, the voltage applied to the second arrangement electrode AE2 may be lower than the voltage applied to the first arrangement electrode AE1. Accordingly, the first quantum dot QD-1 may move closer to the first arrangement electrode AE1 by an electric force.

Different from the above, since the organic light emitting material OR does not have the polarity, the electric force may not act on the organic light emitting material OR even though the voltages are applied to the first arrangement electrode AE1 and the second arrangement electrode AE2. For example, even though the voltages are applied to the first arrangement electrode AE1 and the second arrangement electrode AE2, a distribution of the organic light emitting material OR in the first light emitting layer EML-1 may not be substantially changed. In the disclosure, the expression “The distribution of the organic light emitting material is not substantially changed” may mean that the position of the organic light emitting material OR are not changed by the electric force generated by the electric field formed between the first and second arrangement electrodes AE1 and AE2.

The first quantum dot QD-1 may have a first energy level, and the organic light emitting material OR may have a second energy level higher than the first energy level. In the disclosure, the term “the energy level of the quantum dot or the light emitting material” may mean the level of energy required for the quantum dot or the light emitting material to emit a light.

The first portion PT1 of the first light emitting layer EML-1 may include the organic light emitting material OR in addition to the first quantum dot QD-1. Accordingly, in a case where the energy level of the organic light emitting material OR is lower than the energy level of the first quantum dot QD-1, in case that a voltage for the organic light emitting material OR to emit the light is applied, both the first quantum dot QD-1 and the organic light emitting material OR may emit the light in the first portion PT1.

However, since the organic light emitting material OR has an energy level higher than the energy level of the first quantum dot QD-1, only the first quantum dot QD-1 may emit the light in the first portion PT1. According to an embodiment, as two types of materials with different energy levels are provided, only one type of material may selectively emit the light in the first portion PT1 of the first light emitting layer EML-1. Therefore, a color mixture may be prevented in the first portion PT1.

According to an embodiment, the first quantum dot QD-1 may provide the light having the first color in the first portion PT1 of the first light emitting layer EML-1, and the organic light emitting material OR may provide the light having the second color in the second portion PT2 of the first light emitting layer EML-1. For example, only one first light emitting layer EML-1 disposed in one first opening OH1 may provide the lights having two colors. Accordingly, an integration of the light emitting elements ED-1 and ED-2 (refer to FIG. 6) in the display panel DP may be improved, and a resolution of the display device DD may be improved.

However, since one light emitting layer, e.g., the first light emitting layer EML-1, emits two colors of lights, in a case where thicknesses H1 and H2 of the lower electrodes are the same as each other and thicknesses ET1 and ET2 of the first light emitting layer are the same as each other, at least one light of the two types of lights may not be resonated. For example, a light emitting efficiency of the first light emitting layer EML-1 may be reduced.

However, according to an embodiment, since the thicknesses H1 and H2 of the lower electrodes and the thicknesses ET1 and ET2 of the first and second portions of the first light emitting layer are adjusted, both the light having the first color and the light having the second color generated by the first light emitting layer EML-1 may be resonated.

For example, in case that a distance from an upper surface EGT of the first-first lower electrode to a lower surface ECB of the upper electrode is referred to as a first resonant thickness TH1, the first resonant thickness TH1 may be a resonant thickness of the light having the first color. In case that a distance from an upper surface EBT of the first-second lower electrode to the lower surface ECB of the upper electrode is referred to as a second resonant thickness TH2, the second resonant thickness TH2 may be a resonant thickness of the light having the second color.

Referring to FIG. 7, in case that the thickness H1 of the first-first lower electrode is smaller than the thickness H2 of the first-second lower electrode and the thickness ET1 of the first portion is greater than the thickness ET2 of the second portion, the first thickness TH1 may be greater than the second thickness TH2, however, the disclosure is not limited thereto. According to an embodiment, in case that the thicknesses H1 and H2 of the lower electrodes and the thicknesses ET1 and ET2 of the first and second portions are changed, the first resonant thickness TH1 may be smaller than or equal to the second resonant thickness TH2.

A thickness H3 of the first arrangement insulation portion and the thickness H2 of the first-second lower electrode may be the same, however, the disclosure should not be limited thereto or thereby. For example, the thickness H3 of the first arrangement insulation portion and the thickness H1 of the first-first lower electrode may be the same. According to an embodiment, the thickness H3 of the first arrangement insulation portion may be greater than the thickness H1 of the first-first lower electrode and may be smaller than the thickness H2 of the first-second lower electrode.

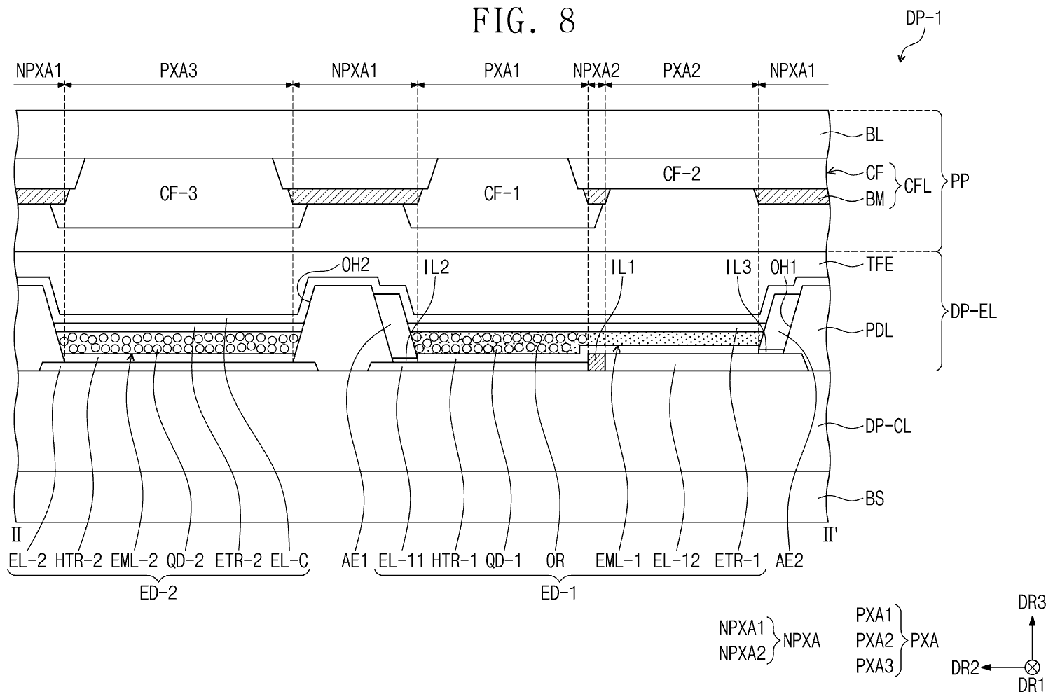

FIG. 8 is a schematic cross-sectional view of a portion of a display device DD-1 according to an embodiment of the disclosure.

Referring to FIG. 8, the display device DD-1 may include a display panel DP-1 and a light control layer PP disposed on the display panel DP-1. In FIG. 8, the same/similar reference numerals denote the same/similar elements in FIGS. 4 to 7, and thus, detailed descriptions of the same/similar elements will be omitted and the following descriptions will be focused on different features.

The display panel DP-1 may be a light emitting type display panel. For example, the display panel DP-1 may be a quantum dot light emitting display panel including a quantum dot light emitting element, however, the disclosure should not be limited thereto or thereby. According to an embodiment, the display panel DP-1 may be an organic light emitting display panel including an organic electroluminescence element.

The light control layer PP may be disposed on the display element layer DP-EL. The light control layer PP may include a base layer BL and a color filter layer CFL.

The base layer BL may provide a base surface on which the color filter layer CFL is disposed. The base layer BL may be a glass substrate, a metal substrate, or a plastic substrate, however, the disclosure should not be limited thereto or thereby. According to an embodiment, the base layer BL may be an inorganic layer, an organic layer, or a composite material layer.

The color filter layer CFL may include a light blocking portion BM, a third filter CF-3 transmitting a light having a first color, a first filter CF-1 transmitting a light having a second color, and a second filter CF-2 transmitting a light having a third color. For example, the third filter CF-3 may be a red color filter, the first filter CF-1 may be a green color filter, and the second filter CF-2 may be a blue color filter.

Each of the filters CF-1, CF-2, and CF-3 may include a polymer photosensitive resin and a pigment or dye. In an embodiment, the first filter CF-1 may include a green pigment or dye, the second filter CF-2 may include a blue pigment or dye, and the third filter CF-3 may include a red pigment or dye, however, the disclosure should not be limited thereto or thereby. According to an embodiment, the first filter CF-1 may include the red pigment or dye, the second filter CF-2 may include the blue pigment or dye, and the third filter CF-3 may include the green pigment or dye.

The light blocking portion BM may be a black matrix. The light blocking portion may include an organic light blocking material or an inorganic light blocking material, which includes a black pigment or dye. The light blocking portion BM may prevent a light leakage phenomenon from occurring and may define a boundary between the filters CF-1, CF-2, and CF-3 adjacent to each other.

Although not shown in FIG. 8, the color filter layer CFL may further include a buffer layer. The buffer layer may serve as a protective layer to protect the filters CF-1, CF-2, and CF-3. The buffer layer may be an inorganic material layer including at least one inorganic material among silicon nitride, silicon oxide, and silicon oxynitride. The buffer layer may have a single-layer structure or a multi-layer structure.

FIG. 8 schematically shows a structure in which the first filter CF-1 of the color filter layer CFL overlaps the second filter CF-2 and the third filter CF-3 in a plan view, however, the disclosure should not be limited thereto or thereby. For example, the first, second, and third filters CF-1, CF-2, and CF-3 may be distinguished from each other by the light blocking portion BM and may not overlap each other in a plan view. According to an embodiment, the first, second, and third filters CF-1, CF-2, and CF-3 may be disposed to correspond to first, second, and third light emitting areas PXA1, PXA2, and PXA3, respectively.

Different from the structure shown in FIG. 8, the display device DD-1 may include a polarizer (not shown) instead of the color filter layer CFL as the light control layer PP. The polarizer (not shown) may block the external light provided to the display panel DP from outside the display panel DP. The polarizer (not shown) may block a portion of the external light. The polarizer (not shown) may reduce a reflected light generated in the display panel DP by the external light.

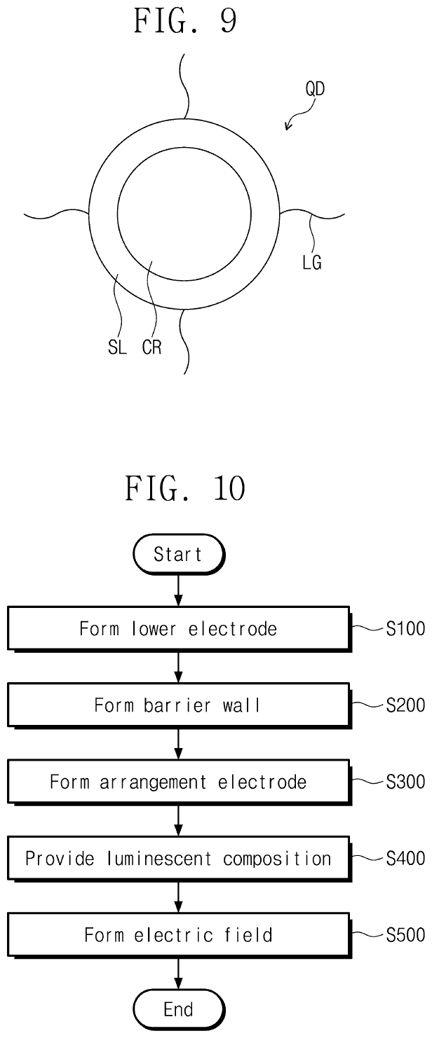

FIG. 9 is a schematic diagram showing a structure of a quantum dot QD according to an embodiment of the disclosure.

Referring to FIG. 9, the quantum dot QD may include a core CR, at least one shell SL surrounding the core CR, and a ligand LG placed outside the shell SL.

The quantum dot QD may include a group II-VI compound, a group III-V compound, a group III-VI compound, a group I-III-VI compound, a group IV-VI compound, a group IV element, a group IV compound, or a combination thereof.

The group II-VI compound may be selected from a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The group III-VI compound may include a binary compound such as In₂S₃ and/or In₂Sc₃, a ternary compound such as InGaS₃ and/or InGaSe₃, or a combination thereof.

The group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof or a quaternary compound selected from the group consisting of AgInGaS₂ and CuInGaS₂.

The group III-V compound may be selected from a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, GaAlNP, and a mixture thereof, and a quaternary compound selected from the group consisting of GaAlNP, GaAlNAs, GaAlNSb, GaAlPAs, GaAlPSb, GaInNP, GaInNAs, GaInNSb, GalnPAs, GaInPSb, InAlNP, InAlNAs, InAlNSb, InAlPAs, InAlPSb, and a mixture thereof. The group III-V compound may further include a group II metal. For instance, InZnP may be selected as a group III-II-V compound.

The group IV-VI compound may be selected from a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The group IV element may be selected from the group consisting of Si, Ge, and a mixture thereof. The group IV compound may be a binary compound selected from the group consisting of SiC, SiGe, and a mixture thereof.

The binary compound, the ternary compound, or the quaternary compound may exist in the particles at a uniform concentration or may exist in the same particle after being divided into plural portions having different concentrations.

An interface between the core CR and the shell SL may have a concentration gradient in which the concentration of elements existing in the shell SL is lowered as a distance from a center decreases.

The quantum dot QD may have a core-shell structure that includes the core CR including the above-mentioned nanocrystal and the shell SL surrounding the core CR. The shell SL of the quantum dot QD may serve as a protective layer to prevent chemical modification of the core CR and to maintain semiconductor properties and/or may serve as a charging layer to impart electrophoretic properties to the quantum dot QD. The shell SL may have a single-layer or multi-layer structure. The shell SL of the quantum dot QD may include a metal oxide, a non-metal oxide, a semiconductor compound, or a combination thereof.

The metal oxides or non-metal oxides may include a binary compound, such as SiO₂, Al₂O₃, TiO₂, ZnO, MnO, Mn₂O₃, Mn₃O₄, CuO, FeO, Fc₂O₃, Fc₃O₄, CoO, Co₃O₄, and NiO, or a ternary compound, such as MgAl₂O₄, CoFc₂O₄, NiFc₂O₄, and CoMn₂O₄, however, the disclosure should not be limited thereto or thereby.

The semiconductor compounds may include CdS, CdSe, CdTe, ZnS, ZnSe, ZnTe, ZnSeS, ZnTeS, GaAs, GaP, GaSb, HgS, HgSc, HgTe, InAs, InP, InGaP, InSb, AlAs, AIP, or AlSb, however, the disclosure should not be limited thereto or thereby.

The quantum dot QD may have a full width at half maximum (FWHM) of a light emission wavelength spectrum of less than or equal to about 45 nm. For example, the quantum dot QD may have a full width at half maximum (FWHM) of a light emission wavelength spectrum of less than or equal to about 40 nm. For example, quantum dot QD may have a full width at half maximum (FWHM) of a light emission wavelength spectrum of less than or equal to about 30 nm or less. The color purity and the color reproducibility may be improved within this range. Since the light emitted through the quantum dot QD may be emitted in all directions, an optical viewing angle may be improved.

The quantum dot QD may have a shape commonly used in the art, however, the disclosure should not be particularly limited. For example, the quantum dot QD may have a shape of spherical, pyramidal, multi-arm, or cubic nanoparticles, nanotubes, nanowires, nanofibers, nanoplatelets, or the like.

The quantum dots may control the color of the emitted light depending on a particle size, and accordingly, the quantum dots may have various emission colors such as blue, red, and green colors. As a size of the quantum dot QD decreases, the quantum dot QD may emit a light in a shorter wavelength region. For example, in the quantum dot QD having a same core CR, a particle size of the quantum dot emitting the green color light may be smaller than a particle size of the quantum dot emitting the red color light. In the quantum dot QD having a same core CR, a particle size of the quantum dot QD emitting the blue color light may be smaller than the particle size of the quantum dot QD emitting the green color light, however, the disclosure should not be limited thereto or thereby. According to an embodiment, the particle size of the quantum dot may be adjusted according to a material of the shell SL and a thickness of the shell SL in the quantum dot QD having a same core CR.

In case that the quantum dots QD have various light emitting colors such as the blue color, the red color, and the green color, the cores CR of the quantum dots QD having different light emitting colors may include different materials from each other.

The ligand LG may be placed on a surface of the shell SL of the quantum dot QD. The ligand LG may increase dispersibility of the quantum dots QD, however, the disclosure is not limited thereto. According to an embodiment, the quantum dot QD may have a structure in which the ligand LG is not placed on the surface of the quantum dot QD.

In an embodiment, the quantum dot QD may have a polarity. For example, the shell SL or the ligand LG of the quantum dot QD may have an electrically positive charge or negative charge. Accordingly, the quantum dot QD may receive the electric force in the electric field, and thus, the quantum dot QD may move by the electric force.

FIG. 10 is a flowchart illustrating a method of manufacturing the display device according to an embodiment of the disclosure. FIGS. 11A to 11F are schematic cross-sectional views illustrating processes of the manufacturing method of the display device according to an embodiment of the disclosure.

Hereinafter, the manufacturing method of the display device will be described with reference to FIGS. 10 and FIGS. 11A to 11F. The following descriptions will be focused on the manufacturing method of the display device without repeating descriptions of structural characteristics of the display device.

Referring to FIG. 10, the manufacturing method of the display device may include forming the lower electrode (S100), forming the barrier wall (S200), forming the arrangement electrode (S300), providing the luminescent composition (S400), and forming the electric field (S500).

Referring to FIG. 11A, the forming of the lower electrode (S100) (refer to FIG. 10) may include providing the base substrate BS, forming the first-first lower electrode EL-11 on the base substrate BS, the first-second lower electrode EL-12 on the base substrate BS and spaced apart from the first-first lower electrode EL-11, and the first arrangement insulation portion IL1 between the first-first lower electrode EL-11 and the first-second lower electrode EL-12, and forming the second lower electrode EL-2 spaced apart from the first lower electrodes EL-11 and EL-12.

The forming of the first-first lower electrode EL-11 and the first-second lower electrode EL-12 may be substantially simultaneously performed, however, the disclosure should not be limited thereto or thereby. For instance, the forming of one of the lower electrodes EL-11 and EL-12 may be performed prior to the forming of another one of the lower electrodes EL-11 and EL-12.

The forming of the first lower electrodes EL-11 and EL-12 and the forming of the second lower electrode EL2 may be substantially simultaneously formed, however, the disclosure should not be limited thereto or thereby.

The first lower electrodes EL-11 and EL-12 and the second lower electrode EL2 may be formed through a sputtering process, however, the disclosure should not be limited thereto or thereby. For example, the first lower electrodes EL-11 and EL-12 and the second lower electrode EL2 may be formed through a physical vapor deposition (PVD) process.

The forming of the barrier wall (S200) (refer to FIG. 10) may be performed. The forming of the barrier wall (S200) (refer to FIG. 10) may include forming the pixel definition layer PDL on the base substrate BS and forming the openings OH1 and OH2 on the pixel definition layer PDL to expose at least a portion of the first-first lower electrode EL-11, at least a portion of the first-second lower electrode EL-12, and at least a portion of the second lower electrode EL2. The openings OH1 and OH2 may be formed by etching portions of the pixel definition layer PDL using a photolithography process.

Referring to FIG. 11B, the forming of the arrangement electrode (S300) (refer to FIG. 10) may be performed to form the first arrangement electrode AE1 and the second arrangement electrode AE2 spaced apart from the first arrangement electrode AE1 in the first opening OH1. The first arrangement electrode AE1 and the second arrangement electrode AE2 may be formed of a metal alloy or a conductive compound.

The first arrangement electrode AE1 and the second arrangement electrode AE2 may be formed through a sputtering process, however, the disclosure should not be limited thereto or thereby. For example, the first arrangement electrode AE1 and the second arrangement electrode AE2 may be formed by a physical vapor deposition (PVD) process.

Referring to FIG. 11C, the providing of the luminescent composition (S400) (refer to FIG. 10) may be performed to provide a first luminescent composition INK1 including the first quantum dot QD-1 (refer to FIG. 7) and the organic light emitting material OR (refer to FIG. 7) in the first opening OH1. The luminescent composition may be a liquid luminescent composition.

The providing of the luminescent composition (S400) may include providing the first luminescent composition INK1 to the first opening OH1 through an inkjet printing method and providing a second luminescent composition INK2 to the second opening OH2 through an inkjet printing method. For example, a first nozzle NZ1 may provide the first luminescent composition INK1 that is in liquid state to the first opening OH1 by discharging the first luminescent composition INK1. A second nozzle NZ2 may provide the second luminescent composition INK2 that is in liquid state to the second opening OH2 by discharging the second luminescent composition INK2.

However, the disclosure should not be limited thereto or thereby. For example, the first luminescent composition INK1 and the second luminescent composition INK2 may be respectively provided to the first opening OH1 and the second opening OH2 by various methods, such as a vacuum deposition method, a spin coating method, a cast method, an LB (Langmuir-Blodgett) method, a laser printing method, an LITI (Laser Induced Thermal Imaging) method, etc.

The process of providing the first luminescent composition INK1 to the first opening OH1 and the process of providing the second luminescent composition INK2 to the second opening OH2 may be performed substantially simultaneously, however, the disclosure should not be limited thereto or thereby. According to an embodiment, one of the process of providing the first luminescent composition INK1 to the first opening OH1 and the process of providing the second luminescent composition INK2 to the second opening OH2 may be completed first, and another one of the process of providing the first luminescent composition INK1 to the first opening OH1 and the process of providing the second luminescent composition INK2 may be performed.

Referring to FIGS. 11D and 11E, the first arrangement electrode AE1 may be connected to a power supply source of the circuit element layer DP-CL through the first conductive line AL1 and may receive the first voltage. The second arrangement electrode AE2 may be connected to a power supply source of the circuit element layer DP-CL through the second conductive line AL2 and may receive the second voltage different from the first voltage. Accordingly, the electric field may be formed between the first arrangement electrode AE1 and the second arrangement electrode AE2.

The forming of the electric field (S500) may be performed to move the first quantum dot QD-1 in a direction closer to the first arrangement electrode AE1 by forming the electric field between the first arrangement electrode AE1 and the second arrangement electrode AE2. FIGS. 11D and 11E schematically show states before and after the movement of the first quantum dot QD-1 due to the formation of the electric field, respectively.

Since the first quantum dot QD-1 may have a polarity, the first quantum dot QD-1 may move in a direction to the first arrangement electrode AE1 by the electric force caused by the electric field. The first voltage and the second voltage may be adjusted to move the first quantum dot QD-1 in the direction to the first arrangement electrode AE1. For example, in case that the first quantum dot QD-1 has a positive charge, the first voltage may be smaller than the second voltage, and in case that the first quantum dot QD-1 has a negative charge, the first voltage may be greater than the second voltage.

The first quantum dot QD-1 may move in the direction to the first arrangement electrode AE1 by the electric force caused by the electric field. Since the first luminescent composition INK1 is not completely dried, the first luminescent composition INK1 may have a fluidity. Accordingly, the first quantum dot QD-1 may move in the direction to the first portion PT1 (refer to FIG. 7) in the first light emitting layer EML-1 that is not completely dried. For example, the first quantum dot QD-1 may be concentrated in the first portion PT1 (refer to FIG. 7) in the first light emitting layer EML-1.

According to an embodiment of the display device DD (refer to FIG. 1) an embodiment, the first quantum dot QD-1 and the organic light emitting material OR may be accommodated in one first opening OH1. Accordingly, in the manufacturing method of the display device DD, multiple openings to respectively accommodate the first quantum dot QD-1 and the organic light emitting material OR may not be required. Thus, a time and cost required to form additional openings on the pixel definition layer PDL may be reduced.

A volume of the first luminescent composition INK1 filled in the first opening OH1 may be greater than a volume of the second luminescent composition INK2 filled in the second opening OH2. Accordingly, even though the liquid luminescent composition is not formed with an extremely small volume, the display device with high-resolution may be manufactured.

Referring to FIG. 11F, a process of forming the first electron transport region ETR-1 and the second electron transport region ETR-2 on the first light emitting layer EML-1 and the second light emitting layer EML-2, respectively, and a process of forming the upper electrode EL-C on the first electron transport region ETR-1 and the second electron transport region ETR-2 may be performed.

According to an embodiment, the process of forming the first and second electron transport regions ETR-1 and ETR-2 may include a process of providing electron transport materials on the first and second light emitting layers EML-1 and EML-2, respectively, a vacuum drying process, and a heat treatment process. The vacuum drying process may include vaporizing the organic solvent (not shown) included in the electron transport materials.

The upper electrode EL-C may be the common electrode. The upper electrode EL-C may be the transmissive electrode, the semi-transmissive electrode, or the reflective electrode. In the case where the upper electrode EL-C is a transmissive electrode, the upper electrode EL-C may include a transparent metal oxide, e.g., indium tin oxide (ITO), indium zinc oxide (IZO), zinc oxide (ZnO), indium tin zinc oxide (ITZO), etc.

A process of forming the encapsulation layer TFE on the display element layer DP-EL may be performed. The encapsulation layer TFE may include an organic layer and an inorganic layer. The organic layer of the encapsulation layer TFE may be formed by a solution process, such as a spin coating, a slit coating, or an inkjet process. The inorganic layer of the encapsulation layer TFE may be formed by a deposition process. For example, the inorganic layer of the encapsulation layer TFE may be formed by a chemical vapor deposition (CVD) process using an open mask.

In a case where an organic material is reflowed to an edge of the display device, a portion of the reflowed organic material may be removed by an ashing process.

Although not shown in figures, the manufacturing method of the display device may further include drying the liquid luminescent composition to dry the first luminescent composition INK1. The drying of the liquid luminescent composition and the forming of the electric field (S500) (refer to FIG. 10) may be formed through a same process. For example, the drying of the liquid luminescent composition process may be performed at least partially overlapping in time with the forming of the electric field (S500) (refer to FIG. 10), however, the disclosure should not be limited thereto or thereby. According to an embodiment, one of the drying of the liquid luminescent composition and the forming of the electric field (S500) (refer to FIG. 10) may be performed first in time.

In the case where the drying of the liquid luminescent composition and the forming of the electric field (S500) (refer to FIG. 10) are performed through a same process as, the time and cost required to manufacture the display device DD may be reduced.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a base substrate;
a barrier wall disposed on the base substrate and provided with a first opening;
a first arrangement electrode disposed in the first opening;
a second arrangement electrode disposed in the first opening and spaced apart from the first arrangement electrode; and
a first light emitting layer disposed in the first opening, comprising a first quantum dot and an organic light emitting material, and including:
a first portion comprising the first quantum dot and the organic light emitting material and disposed adjacent to the first arrangement electrode; and
a second portion comprising the organic light emitting material and disposed adjacent to the second arrangement electrode.

2. The display device of claim 1, wherein
the first quantum dot has a polarity, and
the organic light emitting material does not have a polarity.

3. The display device of claim 1, wherein
the first portion emits a light having a first color, and
the second portion emits a light having a second color different from the first color.

4. The display device of claim 1, wherein
the first arrangement electrode receives a voltage lower than a voltage applied to the second arrangement electrode in case that the first quantum dot has a positive charge, and
the second arrangement electrode receives a voltage lower than the voltage applied to the first arrangement electrode in case that the first quantum dot has a negative charge.

5. The display device of claim 3, further comprising:
a first-first lower electrode disposed on the base substrate and at least partially exposed through the first opening of the barrier wall;
a first-second lower electrode disposed on the base substrate and at least partially exposed through the first opening of the barrier wall; and
a lower electrode insulation portion disposed between the first-first lower electrode and the first-second lower electrode on the base substrate to insulate the first-first lower electrode from the first-second lower electrode.

6. The display device of claim 5, further comprising:
a first arrangement insulation portion disposed between the first-first lower electrode and the first arrangement electrode; and
a second arrangement insulation portion disposed between the first-second lower electrode and the second arrangement electrode.

7. The display device of claim 5, further comprising:
an upper electrode disposed on the first light emitting layer and the barrier wall.

8. The display device of claim 7, further comprising:
a hole transport region disposed between the first-first lower electrode and the first light emitting layer and between the first-second lower electrode and the first light emitting layer; and
an electron transport region disposed between the first light emitting layer and the upper electrode.

9. The display device of claim 7, wherein
the first-first lower electrode has a thickness different from a thickness of the first-second lower electrode, and
the first portion of the first light emitting layer has a thickness different from a thickness of the second portion of the first light emitting layer.

10. The display device of claim 9, wherein
a distance from an upper surface of the first-first lower electrode to a lower surface of the upper electrode corresponds to a resonant thickness of the light having the first color, and
a distance from an upper surface of the first-second lower electrode to the lower surface of the upper electrode corresponds to a resonant thickness of the light having the second color.

11. The display device of claim 1, wherein the first arrangement electrode and the second arrangement electrode at least partially overlap a side surface of the barrier wall that defines the first opening in a plan view.

12. The display device of claim 1, further comprising:
a first conductive line that is in contact with the first arrangement electrode; and
a second conductive line that is in contact with the second arrangement electrode.

13. The display device of claim 12, wherein a voltage applied to the first arrangement electrode through the first conductive line is different from a voltage applied to the second arrangement electrode through the second conductive line.

14. The display device of claim 3, further comprising:
a second light emitting layer, wherein
the barrier wall is provided with a second opening,
the second light emitting layer is disposed in the second opening and comprises a second quantum dot, and
the second light emitting layer emits a light having a third color different from the first and second colors.

15. The display device of claim 14, wherein the first opening has a size greater than a size of the second opening in a plan view.

16. The display device of claim 1, further comprising:
a light control layer disposed on the base substrate,
wherein the light control layer comprises a light blocking portion, a first filter that transmits a light having a first color, a second filter that transmits a light having a second color, and a third filter that transmits a light having a third color.

17. The display device of claim 1, wherein
the first quantum dot comprises:
a core;
at least one shell surrounding the core; and
a ligand placed outside the shell, and the shell or the ligand has a polarity.

18. The display device of claim 1, wherein
the first quantum dot has a first energy level, and
the organic light emitting material has a second energy level higher than the first energy level.

19. A method of manufacturing a display device, comprising:
forming a base substrate, a first-first lower electrode on the base substrate, a first-second lower electrode on the base substrate and spaced apart from the first-first lower electrode, and a lower electrode insulation portion between the first-first lower electrode and the first-second lower electrode;
forming a barrier wall through which an opening is formed to expose at least a portion of each of the first-first lower electrode and the first-second lower electrode;
forming a first arrangement electrode and a second arrangement electrode spaced apart from the first arrangement electrode in the opening;
providing a liquid luminescent composition comprising a quantum dot and an organic light emitting material to the opening; and
forming an electric field between the first arrangement electrode and the second arrangement electrode to move the quantum dot in a direction closer to the first arrangement electrode.

20. The method of claim 19, further comprising:
drying the liquid luminescent composition,
wherein the drying of the liquid luminescent composition and the forming of the electric field are performed through a same process.
